(19) United States
(12) Patent Application Publication
(10) Pub. No.: US 2024/0172376 A1
(43) Pub. Date: May 23, 2024

(54) FOLDABLE DISPLAY DEVICE

(71) Applicant: LG Display Co., Ltd., Seoul (KR)

(72) Inventors: Hyeonyeong LEE, Sejong-si (KR); Kwangmin HYUN, Daegu (KR)

(73) Assignee: LG Display Co., Ltd., Seoul (KR)

(21) Appl. No.: 18/516,522

(22) Filed: Nov. 21, 2023

(30) Foreign Application Priority Data
Nov. 22, 2022 (KR) 10-2022-0156932

(51) Int. Cl. H05K 5/02

(52) U.S. Cl. CPC H05K 5/02

(57) ABSTRACT

A foldable display device includes a display panel, a back plate disposed under the display panel, and a support structure disposed under the back plate and having a bendable area and non-bendable areas disposed on sides of the bendable area. The support structure includes a first support plate having a plurality of opening patterns disposed in the bendable area, and a second support plate disposed on the first support plate and made of a different material from a material of the first support plate. One of the back plate and the second support plate includes a polymer film having a maximum reflectance within a wavelength range of approximately 400 nm to 500 nm. The other one of the back plate and the second support plate includes a polymer film having a maximum light absorbance within a wavelength range of approximately 400 nm to 500 nm.

### CROSS-REFERENCE TO RELATED APPLICATION

This application claims priority to Korean Patent Application No. 10-2022-0156932 filed on Nov. 22, 2022 in the Korean Intellectual Property Office, the entire contents of which are hereby expressly incorporated by reference into the present application.

### BACKGROUND

### Field

The present disclosure relates to a foldable display device. More specifically, the present disclosure relates to a foldable display device capable of reducing a display quality defect issue in which opening patterns of a support structure can be visually recognized.

### Discussion of Related Art

There are various types of display devices that display images, such as a liquid crystal display device (LCD), a light-emitting display device (LED), a quantum dot display device (QD), and an electrophoretic display device (EPD).

Users who watch broadcasts or videos or play video games on the display device tend to prefer a portable display device with a large screen. However, when a screen of a portable display device becomes larger, portability thereof can be greatly reduced.

In order to satisfy both the large screen and portability needs, studies on a foldable display device in which a display panel can be folded and unfolded are being actively conducted.

### SUMMARY OF THE DISCLOSURE

In a foldable display device, a flexible substrate of a display panel is generally very thin. Thus, a back plate that can support the display panel is attached to a lower surface of the display panel. For example, the back plate can be made of a polymer film and attached to the display panel via an adhesive layer. In that case, when folding and unfolding operations of the foldable display device are repeated, however, plastic deformation can occur in the back plate composed of the polymer film in a bendable area of the display panel. This can cause a limitation in that the folding characteristics of the foldable display device can be degraded and images may not be displayed well on the bendable area.

To solve or address these issues, a high rigidity support structure can be attached to the lower surface of the back plate. The support structure includes a high rigidity metal plate with a small thickness. The high rigidity metal plate has high restoring ability. However, an elastic deformation region thereof is narrow, whereby opening patterns can be formed in the bendable area to expand the elastic deformation region of the metal plate. However, the opening patterns formed in the support structure can be visually recognized by a user/viewer in front of the display surface of the display device, thereby causing poor display quality and dissatisfaction with the user.

Accordingly, the inventors of the present disclosure have invented a foldable display device capable of reducing the display quality defect issue in which the opening patterns of the support structure may be visually recognized by a user/viewer.

A technical purpose according to an embodiment of the present disclosure is to provide a foldable display device that has excellent folding characteristics and can reduce the display quality defect issue in which the opening patterns of the support structure are visually recognized by a user/viewer.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A foldable display device according to some embodiments of the present disclosure for achieving the purpose(s) includes a display panel; a back plate disposed under the display panel; and a support structure disposed under the back plate and having a bendable area and non-bendable areas respectively defined on both opposing sides of the bendable area, wherein the support structure includes: a first support plate having a plurality of opening patterns defined in the bendable area thereof; and a second support plate disposed on the first support plate and made of a different material from a material of the first support plate, wherein one of the back plate and the second support plate includes a polymer film having maximum reflectance within a wavelength range of 400 nm to 500 nm, wherein the other of the back plate and the second support plate includes a polymer film having maximum light absorbance within a wavelength range of 400 nm to 500 nm.

A foldable display device according to some embodiments of the present disclosure for achieving the purpose(s) includes a display panel; a back plate disposed under the display panel; and a plate assembly including: an upper plate disposed under the back plate; and a lower plate disposed under the upper plate and having a plurality of opening patterns defined therein, wherein the back plate has maximum light absorbance or maximum reflectance within a wavelength range of 400 nm to 500 nm, wherein when the back plate has maximum light absorbance within a wavelength range of 400 nm to 500 nm, the upper plate has maximum reflectance within a wavelength range of 400 nm to 500 nm, or when the back plate has maximum reflectance within a wavelength range of 400 nm to 500 nm, the upper plate has maximum light absorbance within a wavelength range of 400 nm to 500 nm.

Details of various embodiments of the present disclosure are included in the detailed description and drawings.

According to the embodiments of the present disclosure, the foldable display device can be realized which has excellent folding characteristics and in which the display quality defect in which the opening patterns of the support structure are visually recognized by the viewer in front of a display surface of the foldable display device is reduced or minimized.

According to the embodiments of the present disclosure, the foldable display device capable of improving black color of a display panel can be provided.

Effects of the present disclosure are not limited to the effects mentioned above, and other effects not mentioned will be clearly understood by those skilled in the art from the descriptions below.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a perspective view showing a display device according to embodiments of the present disclosure.

FIG. 2 to FIG. 5 are cross-sectional views showing various examples of display devices according to embodiments of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included in the spirit and scope of the present disclosure as defined by the appended claims.

A shape, a size, a ratio, an angle, a number, etc., disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on”, “above”, “over”, etc. a second element or layer, the first element can be disposed directly on the second element or can be disposed indirectly on the second element with a third element/layer or additional elements/layers being disposed between the first and second elements/layers. It will be understood that when an element or layer is referred to as being “connected to”, or “connected to” another element or layer, it can be directly on, connected to, or connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or sections, these elements, components, regions, layers and/or sections should not be limited by these terms and may not define order or sequence. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term “or” means “inclusive or” rather than “exclusive or”. For example, unless otherwise stated or clear from the context, the expression that ‘x uses a or b’ means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific case, a term can be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, foldable display devices according to embodiments according to the present disclosure will be described in detail with reference to the accompanying drawings. All the components of each foldable display device according to all embodiments of the present disclosure are operatively coupled and configured.

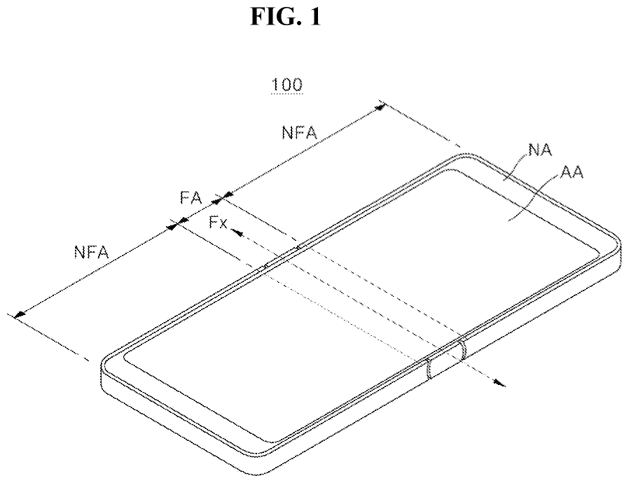

FIG. 1 is a perspective view showing a foldable display device according to an embodiment of the present disclosure.

Referring to FIG. 1, a foldable display device 100 according to the embodiment of the present disclosure can include a display area (or active area) AA, a non-display area (or non-active area) NA, a bendable area (or foldable area) FA, and a non-bendable area (or non-folding area) NFA.

The display area AA can be an area where an image is displayed and can be provided in a display panel of the display device 100. The non-display area NA can be disposed around the display area AA and can be an area in which an image is not displayed. As a variation, the non-display area NA can surround the display area AA entirely or only in part, and multiple separated non-display areas NA can be disposed adjacent to the display area AA.

The bendable area FA can be an area defined around a folding axis Fx and can overlap a portion of the display area AA and a portion of the non-display area NA. For example, the bendable area FA can be an area in which the display device is bent at a predetermined curvature when the foldable display device 100 is folded in at least one of inner folding and outer folding schemes. An area other than the bendable area FA can be the non-bendable area NFA. The non-bendable area NFA can overlap a portion of the display area AA and a portion of the non-display area NA. The bendable area FA can be disposed along a middle region or another region of the display area AA. As a variation, multiple bendable areas FA can be provided depending on the need and design.

In addition, the foldable display device 100 can further include a hinge structure for folding the display panel and a casing for supporting and accommodating therein the display panel. The bendable area FA and the non-bendable area NFA can be equally or similarly applied to each of components of the foldable display device 100.

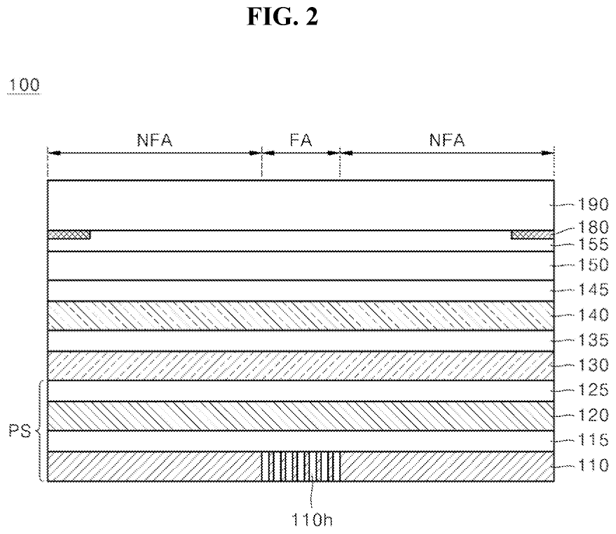

FIG. 2 to FIG. 5 are cross-sectional views illustrating various examples of foldable display devices according to embodiments of the present disclosure, respectively. These cross-sectional views can be views cut along a direction substantially perpendicular to the folding axis Fx direction of the foldable display device 100 of FIG. 1.

Referring to FIG. 2, the foldable display device 100 according to one example of the present disclosure can include a support structure PS, a back plate 130, a display panel 140, a polarization layer 150, a light-blocking layer 180, and a cover window 190.

The display panel 140 can display an image. The display panel 140 can be flexible and can display an image to the user. For example, the display panel 140 can be embodied as a light-emitting diode (LED) display panel. However, the present disclosure is not necessarily limited thereto. The display panel 140 can be of various types, for example, a liquid crystal display panel, an electrophoretic display panel, and the like. When the display panel 140 is embodied as the light-emitting diode (LED) display panel, the display panel 140 can include a thin-film transistor array in which thin-film transistors (including switching thin-film transistors and driving thin-film transistors) are formed on a substrate and in each pixel, a light-emitting area in which an organic light-emitting element or an inorganic light-emitting element connected to the driving thin-film transistor is formed in each pixel, and an encapsulation layer that covers the light-emitting area to prevent moisture and oxygen from an outside from permeating into the light-emitting area.

The display device 100 can further include a touch electrode array formed on the encapsulation layer. In another example, a touch panel including the touch electrode array can be formed on the polarization layer 150.

The back plate 130 can be disposed under the display panel 140 and support the display panel 140 thereon. The display panel 140 applied to the foldable display device 100 can be very thin and flexible. The back plate 130 can prevent a foreign material from being attached to a lower surface of the display panel 140 and can absorb an impact applied from the outside while reinforcing the rigidity of the display panel 140. The back plate 130 can be embodied as a polymer film having maximum reflectance within a wavelength range of 400 nm to 500 nm. The back plate 130 can be embodied as a polymer film having a peak wavelength of the reflectance within a wavelength range of 400 nm to 500 nm. The back plate 130 can be embodied as, for example, a blue polymer film. The polymer film constituting the back plate 130 can be made of, for example, polyimide (PI), polyethylene terephthalate (PET), polycarbonate (PC), or polyethylene naphthalate (PEN). However, the present disclosure is not limited thereto.

A third adhesive layer 135 can be disposed between the back plate 130 and the display panel 140. For example, the back plate 130 can be attached to the lower surface of the display panel 140 via the third adhesive layer 135. The third adhesive layer 135 can be transparent and can be made of optical clear adhesive (OCA) or pressure sensitive adhesive (PSA).

The support structure PS can be disposed under the back plate 130 and can support the display panel 140 thereon. The support structure PS can allow folding and unfolding of the display panel 140 to be easily performed. The support structure PS can dissipate heat generated from the display panel 140 to the outside. The support structure PS can include the bendable area FA and the non-bendable areas NFA respectively disposed on both opposing sides of the bendable area FA.

The support structure PS can include at least one support plate and at least one adhesive layer. The support structure PS can include a first support plate 110 and a second support plate 120.

The support structure PS can further include a first adhesive layer 115 disposed between the first support plate 110 and the second support plate 120. The support structure PS can further include a second adhesive layer 125 disposed on the second support plate 120, and can be attached to a lower surface of the back plate 130 via the second adhesive layer 125. The first support plate 110 can be a lower support plate, and the second support plate 120 can be an upper support plate. The support structure PS can be referred to as a plate assembly. Each of the first and second adhesive layers 115 and 125 can be transparent and can be made of optical clear adhesive (OCA) or pressure sensitive adhesive (PSA).

The first support plate 110 can be made of a metal having excellent thermal conductivity. For example, the first support plate 110 can be made of stainless steel. The first support plate 110 can have a plurality of opening patterns 110h defined in the bendable area FA thereof. The plurality of opening patterns 110h can extend in a direction (hereinafter, referred to as a folding axis direction) parallel to the folding axis Fx (see FIG. 1) of the display device 100, and can be spaced from each other.

A length of each of the plurality of opening patterns 110h can be smaller than a width in the folding axis direction of the first support plate 110. The shape and arrangement of the plurality of opening patterns 110h are not limited to what are shown. Spacings between the opening patterns 110h adjacent to each other in a direction perpendicular to the folding axis Fx can be constant. However, the present disclosure is not limited thereto. The spacings between the opening patterns 110h adjacent to each other in the direction perpendicular to the folding axis Fx can increase as the distance from the opening patterns 110h to the folding axis Fx increases. A spacing between the opening patterns 110h adjacent to each other in the direction perpendicular to the folding axis Fx can have a first spacing in an inner area containing the folding axis Fx, while a spacing between the opening patterns 110h adjacent to each other in the direction perpendicular to the folding axis Fx can have a second spacing greater than the first spacing in an outer area defined on each of both opposing sides of the inner area.

The second support plate 120 can be disposed on the first support plate 110. The second support plate 120 can be made of a material different from that of the first support plate 110. The second support plate 120 can be embodied as a polymer film having maximum light absorbance within a wavelength range of 400 nm to 500 nm. The second support plate 120 can be embodied as a polymer film having a peak wavelength of light absorbance within a wavelength range of 400 nm to 500 nm. The second support plate 120 can be embodied as a yellow polymer film. The polymer film constituting the second support plate 120 can be made of, for example, polyimide (PI), polyethylene terephthalate (PET), polycarbonate (PC), or polyethylene naphthalate (PEN).

However, the present disclosure is not limited thereto. The second support plate 120 can be made of, for example, yellow polyimide (yellow PI).

The polarization layer 150 can be configured to secure visibility of the display panel 140. For example, the polarization layer 150 can include a polarizer and a phase retardation film disposed on one surface of the polarizer. A fourth adhesive layer 145 can be disposed between the polarization layer 150 and the display panel 140. The polarization layer 150 can be attached to an upper surface of the display panel 140 via the fourth adhesive layer 145.

The display panel 140 can include various metal materials used for a thin-film transistor, lines, electrodes, and a light-emitting element layer. External light incident on the display panel 140 can be reflected from the metal material as described above, such that visibility of the foldable display device 100 can be deteriorated due to the reflection of the external light. Therefore, the polarization layer 150 including the phase retardation film can selectively transmit light therethrough to reduce the reflection of the external light incident on the display panel 140, such that outdoor visibility of the foldable display device 100 can be improved. The fourth adhesive layer 145 can be transparent and can be made of optical clear adhesive (OCA) or pressure-sensitive adhesive (PSA).

The cover window 190 can be disposed on the polarization layer 150. The cover window 190 can include a polymer film. For example, the polymer film can be transparent. The polymer film can include, for example, polyethylene terephthalate (PET), colorless polyimide (PI), or a laminate of polyethylene terephthalate (PET) and colorless polyimide (PI). The cover window 190 can further include a hard coating layer formed on the transparent polymer film. The hard coating layer can include a transparent organic/inorganic composite material, thereby effectively protecting the cover window 190 and reducing decrease in light transmittance.

The cover window 190 can protect the polarization layer 150 and the display panel 140 from external impact, moisture, heat, and the like. A fifth adhesive layer 155 can be disposed between the polarization layer 150 and the cover window 190. The cover window 190 can be attached to an upper surface of the polarization layer 150 via the fifth adhesive layer 155. The fifth adhesive layer 155 can be transparent and can be made of optical clear adhesive (OCA) or pressure-sensitive adhesive (PSA).

The light-blocking layer 180 can be formed on an edge area of the cover window 190. The light-blocking layer 180 can be covered with the fifth adhesive layer 155 for attaching the cover window 190 to the polarization layer 150. The light-blocking layer 180 can prevent a driver circuit, various lines, and a pad of the non-display area NA of the display panel 140 from being viewed to the viewer. The light-blocking layer 180 can be formed in a ring shape. For example, the light-blocking layer 180 can be formed in a printing manner using black ink. However, the present disclosure is not limited thereto.

In this embodiment, the second support plate 120 having the maximum light absorbance within the wavelength range of 400 nm to 500 nm and the back plate 130 having the maximum reflectance within the wavelength range of 400 nm to 500 nm can be disposed on the first support plate 110 so as to overlap each other. Thus, the opening patterns 110h of the first support plate 110 may not be visible to the viewer in front of the display surface of the foldable display device. For example, a yellow polymer film reflects a red light component and a green light component of white light, and absorbs a blue light component to render a yellow color. A blue polymer film absorbs a red light component and a green light component of white light and reflects a blue light component to render a blue color. When the foldable display device is exposed to external light such as sunlight, the yellow polymer film absorbs the blue light and the blue polymer film absorbs red light and green light. Thus, when the yellow and blue films overlap each other to form a stack, the stack renders a dark gray close to black. Therefore, when the second support plate 120 and the back plate 130 as described above overlap each other to form a stack, the stack renders the dark gray. Thus, the opening patterns 110h of the first support plate 110 can be prevented from being visible to the viewer in front of the display surface of the foldable display device, such that black color of the foldable display device can be improved.

Referring to FIG. 2, an example in which the second support plate 120 is made of a polymer film having maximum light absorbance within the wavelength range of 400 nm to 500 nm, and the back plate 130 is made of a polymer film having maximum reflectance within the wavelength range of 400 nm to 500 nm has been described. Conversely, an example in which the second support plate 120 is made of a polymer film having maximum reflectance within the wavelength range of 400 nm to 500 nm, and the back plate 130 is made of a polymer film having maximum light absorbance within a wavelength range of 400 nm to 500 nm can be proposed in accordance with the present disclosure. Even in this case, the opening patterns 110h of the first support plate 110 can be prevented from being visible to the viewer in front of the display surface of the foldable display device, such that black color visibility of the foldable display device can be improved.

In the foldable display device, at least one of the first adhesive layer 115 or 116 disposed between the first support plate 110 and the second support plate 120, the second adhesive layer 125 or 126 disposed between the second support plate 120 and the back plate 130, or the third adhesive layer 135 or 136 disposed between the back plate 130 and the display panel 140 can contain black pigment or dye. At least at least one black adhesive layer can be further disposed on the first support plate 110. Thus, the opening patterns 110h of the first support plate 110 can be prevented from being visible to the viewer in front of the display surface of the foldable display device, and thus, the black color of the foldable display device can be further improved.

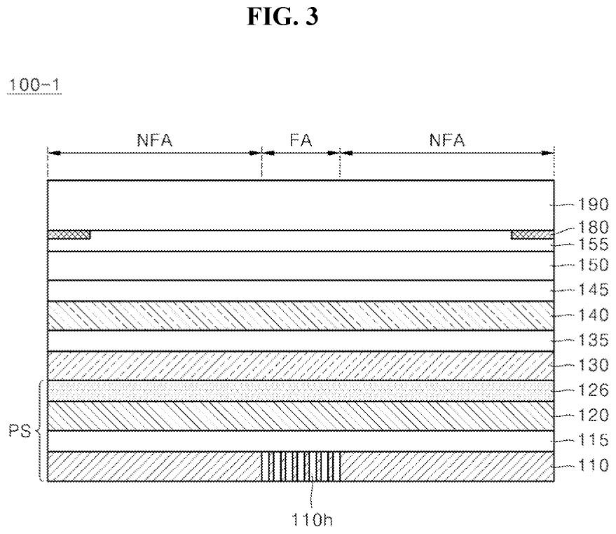

For example, referring to a foldable display device 100-1 of FIG. 3, one black adhesive layer can be disposed on the first support plate 110. The second adhesive layer 126 disposed between the second support plate 120 and the back plate 130 can contain the black pigment or dye.

In another example, unlike what is shown in FIG. 3, the first adhesive layer 115 disposed between the first support plate 110 and the second support plate 120 can be free of the black pigment or dye. Alternatively, the third adhesive layer 135 disposed between the back plate 130 and the display panel 140 can contain the black pigment or dye.

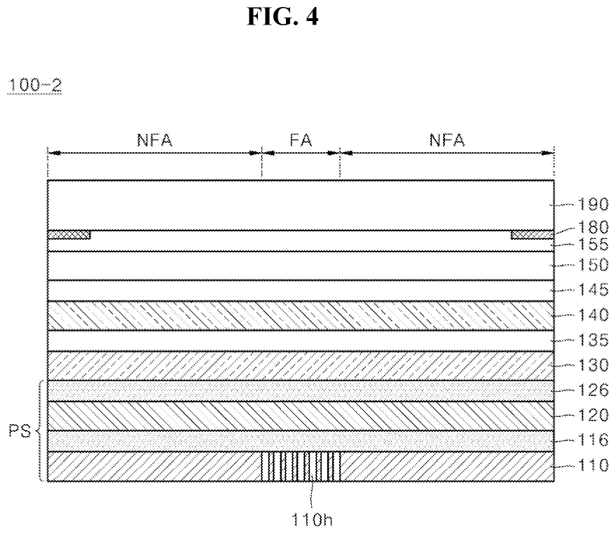

For example, referring to a foldable display device 100-2 of FIG. 4, two black adhesive layers can be disposed on the first support plate 110. Each of the first adhesive layer 116 disposed between the first support plate 110 and the second support plate 120, and the second adhesive layer 126 disposed between the second support plate 120 and the back plate 130 can contain the black pigment or dye.

In another example, unlike what is shown in FIG. 4, each of the first adhesive layer 116 disposed between the first support plate 110 and the second support plate 120, and the third adhesive layer 135 disposed between the back plate 130 and the display panel 140 can contain the black pigment or dye. Further, each of the second adhesive layer 126 disposed between the second support plate 120 and the back plate 130, and the third adhesive layer 135 disposed between the back plate 130 and the display panel 140 can contain the black pigment or dye.

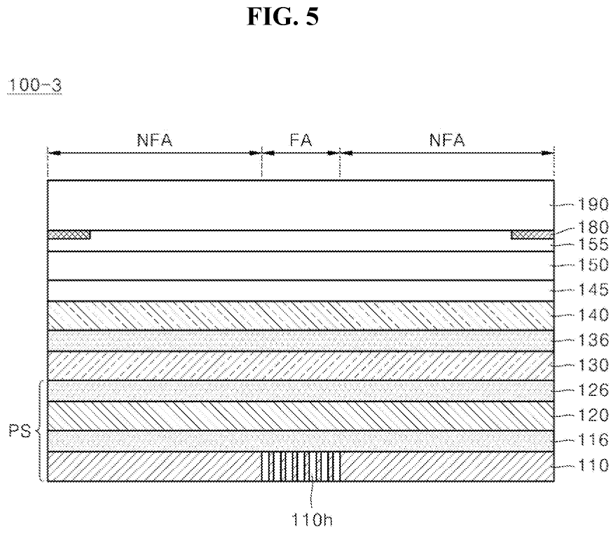

For example, referring to a foldable display device 100-3 of FIG. 5, three black adhesive layers can be disposed on the first support plate 110. Each of the first adhesive layer 116 disposed between the first support plate 110 and the second support plate 120, the second adhesive layer 126 disposed between the second support plate 120 and the back plate 130, and the third adhesive layer 136 disposed between the back plate 130 and the display panel 140 can contain the black pigment or dye.

A foldable display device according to embodiments of the present disclosure can be described as follows.

A first aspect of the present disclosure provides a foldable display device comprising: a display panel; a back plate disposed under the display panel; and a support structure disposed under the back plate and having a bendable area and non-bendable areas respectively defined on both opposing sides of the bendable area, wherein the support structure includes: a first support plate having a plurality of opening patterns defined in the bendable area thereof; and a second support plate disposed on the first support plate and made of a different material from a material of the first support plate, wherein the back plate includes a polymer film having maximum reflectance within a wavelength range of 400 nm to 500 nm, wherein the second support plate includes a polymer film having maximum light absorbance within a wavelength range of 400 nm to 500 nm.

In some implementations of the first aspect, the back plate includes a blue polymer film, and the second support plate includes a yellow polymer film.

In some implementations of the first aspect, the foldable display device further comprises: a first adhesive layer disposed between the first support plate and the second support plate; a second adhesive layer disposed between the second support plate and the back plate; and a third adhesive layer disposed between the back plate and the display panel, wherein at least one of the first adhesive layer, the second adhesive layer, or the third adhesive layer contains black pigment or dye.

In some implementations of the first aspect, the second adhesive layer contains the black pigment or dye.

In some implementations of the first aspect, each of the first adhesive layer and the second adhesive layer contains the black pigment or dye.

In some implementations of the first aspect, each of the first adhesive layer, the second adhesive layer and the third adhesive layer contains the black pigment or dye.

A second aspect of the present disclosure provides a foldable display device comprising: a display panel; a back plate disposed under the display panel; and a support structure disposed under the back plate and having a bendable area and non-bendable areas respectively defined on both opposing sides of the bendable area, wherein the support structure includes: a first support plate having a plurality of opening patterns defined in the bendable area thereof; and a second support plate disposed on the first support plate and made of a different material from a material of the first support plate, wherein the back plate includes a polymer film having maximum light absorbance within a wavelength range of 400 nm to 500 nm, wherein the second support plate includes a polymer film having maximum reflectance within a wavelength range of 400 nm to 500 nm.

In some implementations of the second aspect, the back plate includes a yellow polymer film, and the second support plate includes a blue polymer film.

In some implementations of the second aspect, the foldable display device further comprises: a first adhesive layer disposed between the first support plate and the second support plate; a second adhesive layer disposed between the second support plate and the back plate; and a third adhesive layer disposed between the back plate and the display panel, wherein at least one of the first adhesive layer, the second adhesive layer, or the third adhesive layer contains black pigment or dye.

A third aspect of the present disclosure provides a foldable display device comprising: a display panel; a back plate disposed under the display panel; and a plate assembly including: an upper plate disposed under the back plate; and a lower plate disposed under the upper plate and having a plurality of opening patterns defined therein, wherein the back plate has maximum light absorbance or maximum reflectance within a wavelength range of 400 nm to 500 nm, wherein when the back plate has maximum light absorbance within a wavelength range of 400 nm to 500 nm, the upper plate has maximum reflectance within a wavelength range of 400 nm to 500 nm, or when the back plate has maximum reflectance within a wavelength range of 400 nm to 500 nm, the upper plate has maximum light absorbance within a wavelength range of 400 nm to 500 nm.

In some implementations of the third aspect, the foldable display device further comprises at least one adhesive layer disposed between the display panel and the lower plate, wherein the at least one adhesive layer contains black pigment or dye.

Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects. The scope of protection of the present disclosure should be interpreted according to the scope of claims, and all technical ideas within an equivalent scope thereto should be interpreted as being included in the scope of rights of the present disclosure.

What is claimed is:

1. A foldable display device comprising:
a display panel;
a back plate disposed under the display panel; and
a support structure disposed under the back plate, and having a bendable area and at least one non-bendable area disposed adjacent to the bendable area,
wherein the support structure includes:
a first support plate having a plurality of opening patterns disposed in the bendable area; and
a second support plate disposed on the first support plate and made of a different material from a material of the first support plate,
wherein the back plate includes a polymer film having a maximum reflectance within a wavelength range of approximately 400 nm to 500 nm, and
wherein the second support plate includes a polymer film having a maximum light absorbance within a wavelength range of approximately 400 nm to 500 nm.

2. The foldable display device of claim 1, wherein the back plate includes a blue polymer film, and the second support plate includes a yellow polymer film.

3. The foldable display device of claim 1, wherein the foldable display device further comprises:
a first adhesive layer disposed between the first support plate and the second support plate;
a second adhesive layer disposed between the second support plate and the back plate; and
a third adhesive layer disposed between the back plate and the display panel,
wherein at least one of the first adhesive layer, the second adhesive layer, or the third adhesive layer contains black pigment or dye.

4. The foldable display device of claim 3, wherein the second adhesive layer contains the black pigment or dye.

5. The foldable display device of claim 3, wherein each of the first adhesive layer and the second adhesive layer contains the black pigment or dye.

6. The foldable display device of claim 3, wherein each of the first adhesive layer, the second adhesive layer and the third adhesive layer contains the black pigment or dye.

7. A foldable display device comprising:
a display panel;
a back plate disposed under the display panel; and
a support structure disposed under the back plate, and having a bendable area and at least one non-bendable area disposed adjacent to the bendable area,
wherein the support structure includes:
a first support plate having a plurality of opening patterns disposed in the bendable area; and
a second support plate disposed on the first support plate and made of a different material from a material of the first support plate,
wherein the back plate includes a polymer film having a maximum light absorbance within a wavelength range of approximately 400 nm to 500 nm,
wherein the second support plate includes a polymer film having a maximum reflectance within a wavelength range of approximately 400 nm to 500 nm.

8. The foldable display device of claim 7, wherein the back plate includes a yellow polymer film, and the second support plate includes a blue polymer film.

9. The foldable display device of claim 7, wherein the foldable display device further comprises:
a first adhesive layer disposed between the first support plate and the second support plate;
a second adhesive layer disposed between the second support plate and the back plate; and
a third adhesive layer disposed between the back plate and the display panel,
wherein at least one of the first adhesive layer, the second adhesive layer, or the third adhesive layer contains black pigment or dye.

10. A foldable display device comprising:
a display panel;
a back plate disposed under the display panel; and
a support structure disposed under the back plate, and having a bendable area and at least one non-bendable area disposed adjacent to the bendable area,
wherein the support structure includes a first support plate formed of high rigidity metal and having a plurality of opening patterns disposed in the bendable area, and
wherein the back plate includes a polymer film having a maximum light absorbance within a wavelength range of approximately 400 nm to 500 nm, or includes a polymer film having a maximum reflectance within a wavelength range of approximately 400 nm to 500 nm.

11. The foldable display device of claim 10, wherein the support structure further includes a second support plate disposed between the back plate and the first support plate, and
wherein the second support plate has a maximum light absorbance within a wavelength range of approximately 400 nm to 500 nm, or includes a polymer film having a maximum reflectance within a wavelength range of approximately 400 nm to 500 nm.

12. The foldable display device of claim 10, wherein the back plate includes a blue polymer film or a yellow polymer film.

13. The foldable display device of claim 11, wherein the second support plate includes a blue polymer film or a yellow polymer film.

14. The foldable display device of claim 11, wherein the foldable display device further comprises:
a first adhesive layer disposed between the first support plate and the second support plate;
a second adhesive layer disposed between the second support plate and the back plate; and
a third adhesive layer disposed between the back plate and the display panel,
wherein at least one of the first adhesive layer, the second adhesive layer, or the third adhesive layer contains black pigment or dye.
